(19) United States
(12) Patent Application Publication
(10) Pub. No.: US 2024/0222927 A1
(43) Pub. Date: Jul. 4, 2024

(54) ELECTRONIC MODULE FOR A MAGNETIC SWITCHING NETWORK TO PRODUCE A PULSE OF THE PULSED OUTPUT LIGHT BEAM

(71) Applicant: Cymer, LLC, San Diego, CA (US)

(72) Inventors: Paul Christopher Melcher, EI Cajion, CA (US); Yuda Wang, San Diego, CA (US); Changqi You, San Diego, CA (US)

(21) Appl. No.: 18/556,835

(22) PCT Filed: Apr. 4, 2022
(86) PCT No.: PCT/US2022/023322

§ 371 Date: Oct. 23, 2023

Related U.S. Application Data
(60) Provisional application No. 63/180,997, filed on Apr. 28, 2021.

(51) Int. Cl. H01S 3/097; G03F 7/00; G03F 7/20; H01S 3/10; H01S 3/23; H01S 3/225

(52) U.S. Cl. CPC H01S 3/09702; G03F 7/2004; G03F 7/70025; G03F 7/70041; G03F 7/70525; G03F 7/7055; H01S 3/10007; H01S 3/2366; H01S 3/225

(57) ABSTRACT

An apparatus includes: a magnetic switching network configured to activate an excitation mechanism in a discharge chamber. The magnetic switching network includes: an initial energy storage node configured to receive electrical current from an electrical charger; an additional energy storage node; and at least one electrical element between the initial energy storage node and the additional energy storage node. The apparatus also includes an electronic network electrically connected to the additional energy storage node, the electronic network configured to control a voltage at the additional energy storage node.

### CROSS REFERENCE TO RELATED APPLICATIONS

This application is a United States National Phase Patent Application of International Patent Application Number PCT/US2022/023322, filed on Apr. 4, 2022, which claims priority to U.S. Application No. 63/180,997, filed Apr. 28, 2021, titled ELECTRONIC MODULE FOR A MAGNETIC SWITCHING NETWORK, each of which are incorporated herein in their entireties by reference.

### TECHNICAL FIELD

This disclosure relates to an electronic module for a magnetic switching network. The magnetic switching network may be used in an optical system. The optical system may be or include, for example, an excimer laser and may produce deep ultraviolet (DUV) light.

### BACKGROUND

Photolithography is the process by which semiconductor circuitry is patterned on a substrate such as a silicon wafer. A photolithography optical source (or light source) provides the deep ultraviolet (DUV) light used to expose a photoresist on the wafer. One type of gas discharge light source used in photolithography is known as an excimer light source or laser. An excimer light source typically uses a combination of one or more noble gases, such as argon, krypton, or xenon, and a reactive such as fluorine or chlorine. The excimer light source derives its name from the fact that under the appropriate condition of electrical stimulation (energy supplied) and high pressure (of the gas mixture), a pseudo-molecule called an excimer is created, which only exists in an energized state and gives rise to amplified light in the ultraviolet range. An excimer light source produces a light beam that has a wavelength in the deep ultraviolet (DUV) range and this light beam is used to pattern semiconductor substrates (or wafers) in a photolithography apparatus. The excimer light source can be built using a single gas discharge chamber or using a plurality of gas discharge chambers.

### SUMMARY

In one aspect, a system includes: a first optical subsystem configured to produce a pulsed seed light beam, the first optical subsystem including: a first chamber configured to hold a first gaseous gain medium; and a first excitation mechanism in the first chamber; a second optical subsystem configured to produce a pulsed output light beam based on the pulsed seed light beam, the second optical subsystem including: a second chamber configured to hold a second gaseous gain medium; and a second excitation mechanism in the second chamber; a first magnetic switching network configured to activate the first excitation mechanism, where activating the first excitation mechanism causes the first optical subsystem to produce a pulse of the pulsed seed light beam, and the first magnetic switching network includes: a first initial energy storage node, a first additional energy storage node, a first magnetic switch electrically connected to the first additional energy storage node, and a first inductor between the first initial energy storage node and the first additional energy storage node, and where the first initial energy storage node is configured to receive electrical current from an electrical charger; a second magnetic switching network configured to activate the second excitation mechanism, where activating the second excitation mechanism causes the second optical subsystem to produce a pulse of the pulsed output light beam, and the second magnetic switching network includes: a second initial energy storage node, a second additional energy storage node, a second magnetic switch electrically connected to the second additional energy storage node, and a second inductor between the second initial energy storage node and the second additional energy storage node, and where the second initial energy storage node is configured to receive electrical current from the electrical charger; and an electronic network electrically connected to the first additional energy storage node and the second additional energy storage node, where the electronic network is configured to control a voltage difference between the first additional energy storage node and the second additional energy storage node.

Implementations may include one or more of the following features.

The electronic network may be configured to control the voltage difference between the first additional energy storage node and the second additional energy storage node by reducing the voltage difference. The electronic network may be configured to control the voltage difference between the first additional energy storage node and the second additional energy storage node by eliminating the voltage difference. Eliminating the voltage difference may include causing the first additional energy storage node and the second additional energy storage node to be at the same voltage.

The first additional energy storage node may include a first energy storage device, and the second additional energy storage node may include a second energy storage device. The electronic network may be configured to control the voltage difference between the first additional energy storage node and the second additional energy storage node only when the electronic network is in an active state, and the electronic network may be in the active state when the first energy storage device and the second energy storage device are accumulating electrical charge. The electronic network may be configured to control the voltage difference between the first additional energy storage node and the second additional energy storage node only when the electronic network is in an active state, the electronic network may be in the active state at a first time, and the electronic network may transition out of the active state a pre-defined amount of time after the first time.

The electronic network may be configured to control the voltage difference between the first additional energy storage node and the second additional energy storage node only when in an active state, the electronic network may be in the active state after the first magnetic switching network activates the first excitation mechanism and the second magnetic switching network activates the second excitation mechanism, and the electronic network may transition out of the active state prior to a subsequent activation of the first excitation mechanism and prior to a subsequent activation of the second excitation mechanism.

The electronic network may be configured to control the voltage difference between the first additional energy storage node and the second additional energy storage node only when in an active state, and the electronic network may be configured to be in the active state after each activation of the first and second excitation mechanisms and to transition out of the active state before the next activation of the first excitation mechanism and the second excitation mechanism.

In some implementations, each of the first additional energy storage node and the second additional energy storage node includes at least one capacitor.

The first additional energy storage node may be one of a plurality of additional storage nodes in the first magnetic switching network, and the second additional energy storage node may be one of a plurality of additional storage nodes in the second magnetic switching network, and the system further includes a second electronic network electrically connected to one of the additional storage nodes in the first magnetic switching network other than the first additional storage node and to one of the additional storage nodes in the second magnetic switching network other than the second additional storage node.

At least one of the plurality of additional storage nodes in the first magnetic switching network may be a primary side of a transformer, and at least one of the plurality of additional storage nodes in the second magnetic switching network may be a primary side of a transformer.

The electronic network may include at least two transistors.

The electronic network includes a plurality of controllable switches, and each controllable switch may be in parallel with a resistive network. The system also may include a ground path network between the electronic network and ground. The ground path network may include a transistor and a resistor.

The electronic network may include: a first electronic network electrically connected between the first additional energy storage node and ground; and a second electronic network electrically connected between the second additional energy storage node and ground. Each of the first electronic network and the second electronic network may include a voltage-controlled switch in series with a resistive element.

The first initial energy storage node and the second initial energy storage node being configured to receive electrical current from a resonant charger.

The system also may include a second electronic network. The second electronic network may be electrically connected to an anode of a diode that is electrically connected to the first initial energy storage node and to an anode of a diode that is electrically connected to the second initial energy storage node.

The system also may include a second electronic network. The second electronic network may be electrically connected to a cathode of a diode that is electrically connected to the first initial energy storage node and to a cathode of a diode that is electrically connected to the second initial energy storage node.

The first magnetic switching network also may include a first switch configured to control an electrical connection between the first initial energy storage node and the first additional energy storage node, and the second magnetic switching network also may include a second switch configured to control an electrical connection between the second initial energy storage node and the second additional energy storage node.

The first magnetic switch may include a first saturable reactor, and the second magnetic switch may include a second saturable reactor.

In another aspect, an apparatus includes: a magnetic switching network configured to activate an excitation mechanism in a discharge chamber. The magnetic switching network includes: an initial energy storage node configured to receive electrical current from an electrical charger; an additional energy storage node; and at least one electrical element between the initial energy storage node and the additional energy storage node. The apparatus also includes an electronic network electrically connected to the additional energy storage node, the electronic network configured to control a voltage at the additional energy storage node.

Implementations may include one or more of the following features.

The electronic network may include at least one controllable switch, and the controllable switch may include a first state in which current does not flow in the controllable switch and a second state in which current flows in the controllable switch. The controllable switch may be controlled to be in the first state when an energy storage device electrically connected to the additional energy storage node is receiving electrical charge. The controllable switch may be controlled to be in the second state when the energy storage device is discharging electrical charge. The controllable switch may be controlled to be in the first state after an energy storage device electrically connected to the additional energy storage node has received a threshold amount of electrical charge. The controllable switch may be controlled to be in the first state after the magnetic switching network activates the excitation mechanism a first time, and the controllable switch is controlled to be in the second state before the magnetic switching network activates the excitation mechanism a second time. The first time and the second time may be consecutive activations of the excitation mechanism. In some implementations, between any two consecutive activations of the excitation mechanism, the controllable switch is controlled to be in the first state and is then controlled to transition from the first state to the second state.

In another aspect, a control system includes: a control interface configured to trigger an electronic network, the electronic network electrically connected to a first energy storage node in a first magnetic switching network and to a second energy storage node in a second magnetic switching network. Each of the first magnetic switching network and the second magnetic switching network also include an initial energy storage node that receives electrical charge from a resonant charger. The control system also includes a switch control configured to command the control interface to: provide a trigger to the electronic network to thereby cause the electronic network to electrically connect the first energy storage node to the second energy storage node and to reduce a voltage difference between the first energy storage node and the second energy storage node.

Implementations of any of the techniques described above may include a system, a method, a process, a device, or an apparatus. The details of one or more implementations are set forth in the accompanying drawings and the description below. Other features will be apparent from the description and drawings, and from the claims.

### DRAWING DESCRIPTION

FIG. 1A is a block diagram of an example of a system.

FIG. 1B is a schematic of an example of a switching network.

FIG. 1C is an example of a magnetization curve.

FIG. 1D is an example of electrical current as a function of time.

FIG. 2 is a block diagram of an example of a two-stage laser system.

FIG. 3 is a block diagram of an example of a control system.

FIG. 4 is a schematic of another example of a switching network.

FIGS. 5A-5C are schematics of examples of electronic modules.

FIGS. 6-7 are flow charts of examples of operating a magnetic switching network.

FIG. 8A is a block diagram of an example of a deep ultraviolet (DUV) optical system.

FIG. 8B is a block diagram of an example of a projection optical system that may be used in the DUV optical system of FIG. 8A.

FIG. 9 is a block diagram of another example of a DUV optical system.

### DETAILED DESCRIPTION

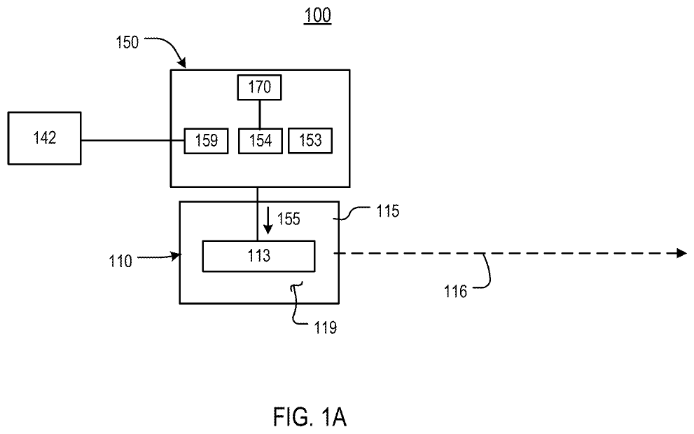

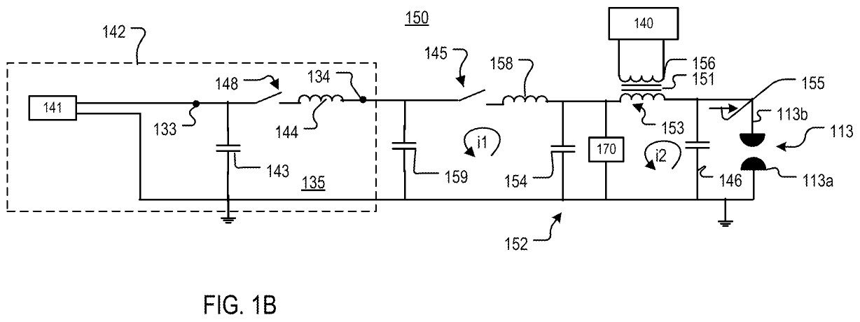

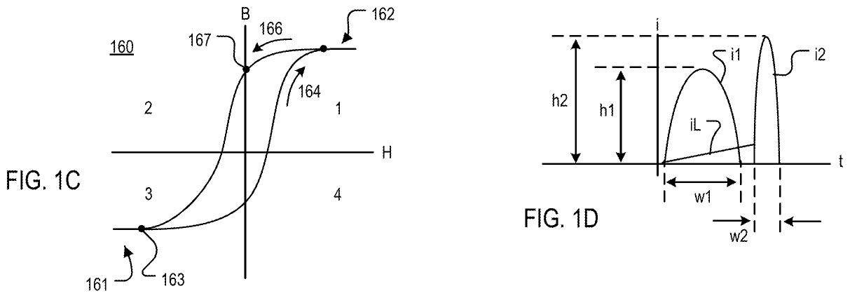

FIG. 1A is a block diagram of an example of a system 100. The system 100 includes an optical source 110. The optical source 110 may be a deep ultraviolet (DUV) optical source that is used to expose semiconductor wafers. The optical source 110 includes a discharge chamber 115 that encloses a gain medium 119 and an excitation mechanism 113. The excitation mechanism 113 is activated by an electrical pulse 155. The electrical pulse 155 is produced by a switching network 150. Activating the excitation mechanism 113 creates population inversion in the gain medium 119 and a pulse of light is produced. The switching network 150 generates a train of electrical pulses 155 that are provided to the excitation mechanism 113 such that the optical source 110 produces a pulsed light beam 116.

The switching network 150 includes various components, including an initial energy storage node 159, an additional energy storage node 154, and a magnetic switch 153. The initial energy storage node 159 receives and stores electrical energy from an electrical charger 142. The initial energy storage node 159 provides the stored electrical energy to the additional storage node 154, which is electrically connected to the magnetic switch 153. The magnetic switch 153 has a variable impedance, and the electrical pulse 155 is produced when the impedance of the magnetic switch 153 is low. The magnetic switch 153 may be, for example, a saturable reactor.

The switching network 150 also includes an electronic module 170 that is electrically connected to the additional energy storage node 154. As discussed in more detail below, the electronic module 170 controls a voltage at the additional energy storage node 154. Controlling the voltage at the additional energy storage node 154 improves the performance of the system 100 and the optical source 110. For example, controlling the voltage at the additional energy storage node 154 allows greater control over the operating point of the magnetic switch 153 and thus provides greater control over the timing of the production of the electrical pulse 155 and the timing of the pulses in the pulsed light beam 116.

FIG. 1B is a schematic of an example of the switching network 150 and a pulse generating network 152. The switching network 150 includes the initial energy storage node 159 (which is a capacitor in this example), the additional energy storage node 154 (which is a capacitor in this example), an inductor 158, the magnetic switch 153, and the electronic module 170. The initial energy storage node 159 is electrically connected to the electrical charger 142. The inductor 158 is between the initial energy storage node 159 and the additional energy storage node 154. The electronic module 170 is in parallel with the additional energy storage node 154 in the example of FIG. 1B.

The magnetic switch 153 includes a magnetic core 151. The magnetic core 151 is any material that becomes magnetized in response to being exposed to an external magnetic field. The magnetic core 151 may be a magnetic material with a relatively high permeability, such as, for example, a ferromagnetic material such as iron or an iron alloy. Permeability (μ) is a measure of the degree of magnetization that the material obtains in response to an applied magnetic field. Although a ferromagnetic material is given as an example, other materials may be used.

In the example shown in FIG. 1B, the magnetic switch 153 is magnetically coupled to a control coil 156 and a control module 140 via the magnetic core 151. For example, the control coil 156 may be a coiled electrical wire that is wrapped around the magnetic core 151. The magnetic switch 153 also may include an electrically conductive coil wrapped around the magnetic core 151. The control module 140 may include a current and/or voltage source that produces a bias current. The bias current may be used to control the impedance of the magnetic core 151. The magnetic switch 153 may be implemented without the control module 140.

FIG. 1C is an illustration of an example of a magnetization curve 160 of the magnetic core 151. The magnetization curve in FIG. 1C is a plot of magnetization (B) of the magnetic core 151 as a function of magnetic field strength (H). The units of magnetization (B) are Teslas (T), and the units of the magnetic field strength (H) are amperes per meter (A/m). At any particular time, the magnetic switch 153 has an operating point that is defined by the value of the magnetization (B) and the value of the magnetic field strength (H) at that particular time.

The magnetization curve 160 is non-linear and the magnetic core 151 experiences magnetic hysteresis. When a magnetic field having a first direction is applied to the magnetic core 151, the atomic dipoles in the material of the core 151 align with the first direction and the material of the core 151 becomes magnetized in a first direction. When the first magnetic field is removed, some of the alignment is retained. Thus, even when there is no external magnetic field (that is, when H=0), the magnetic material of the core 151 retains some magnetization.

The magnetic core 151 has a forward saturation region 162 and a reverse saturation region 161. The magnetic core 151 is saturated when the application of the external magnetic field no longer produces a significant change in the magnetization of the material of the magnetic core 151. The impedance of the magnetic core 151 is lowest in the regions 162 and 161. When the magnetic core 151 is not saturated and the magnetization (B) is between the regions 161 and 162, the magnetic switch 153 has a relatively high impedance.

Referring again to FIG. 1B, the electrical charger 142 includes a high-voltage power supply 141 and a resonant charging circuit 135. The resonant charging circuit 135 is electrically connected to an output node 133 of the high-voltage power supply 141. The high-voltage power supply 141 may be, for example, a 32 kiloWatt (kW) power supply capable of supplying 900 V DC at the output node 133. The high-voltage power supply 141 may have other specifications and characteristics. For example, the power supply 141 may be a 52 kW power supply capable of supplying 800 V DC at the output node 133. The power supply 141 may be configured to provide other power and voltage amounts, and the above values of voltage and power are provided as examples. Moreover, the voltage at the output node 133 may be positive or negative relative to ground. In other words, in the example of the 32 kW power supply capable of supplying 900 V DC, the voltage at the output node 133 may be +900V or −900V. In the example discussed below, the power supply 141 has a negative polarity.

The resonant charging circuit 135 includes a capacitor 143, a switch 148, and an inductor 144. The switch 148 may be, for example, a transistor such as an insulated gate bipolar transistor (IGBT). The capacitor 143 is electrically connected to the output node 133 and ground. The switch 148 is electrically connected to the output node 133, and the switch 148 is in series with the inductor 144. The resonant charging circuit 135 shown in FIG. 1B is an example. In other implementations, the resonant charging circuit 135 may include additional components such as, for example, diodes and additional switches. In still other implementations, a high-voltage capacitor charging power supply is used instead of the resonant charging circuit 135.

The high-voltage power supply 141 applies a voltage across the capacitor 143. Electrical charge accumulates in the capacitor 143, and the voltage across the capacitor 143 increases or remains constant until the switch 148 closes. An electrical pulse-generation cycle begins when the switch 148 closes. The production of one instance of the electrical pulse 155 (and one corresponding pulse of the light beam 116) is referred to as the electrical pulse-generation cycle. When the switch 148 closes, the electrical charge stored in the capacitor 143 is discharged and flows to the initial energy storage node 159, which is electrically connected to an output node 134 of the resonant charging circuit 135. The switch 148 may be triggered to close after the voltage across the capacitor 143 reaches a specified voltage and/or after a specified time. The specified voltage value may be a commanded voltage, pre-set voltage value, or other voltage value. After the switch 148 closes, the charge on the capacitor 143 is discharged. The switch 148 is opened when the target voltage is achieved on the output node 134. The target voltage may be, for example, several hundred volts, a voltage that is about twice the voltage across the capacitor 143, or a voltage that is between these values.

In some implementations, the capacitor 143 has a much greater capacitance than the energy storage node 159. For example, in some implementations, the capacitance of the capacitor 143 is at least 10 times greater than the capacitance of the capacitor 159. The relatively large difference in capacitance allows the energy storage node 159 to charge up to about twice the voltage of the capacitor 143. The large difference in capacitance also means that there is relatively little voltage discharge on the capacitor 143.

The electrical charge from the capacitor 143 accumulates in the initial energy storage node 159. The voltage across the initial energy storage node 159 increases to the commanded voltage and remains at the commanded voltage until a switch 145 closes. When the switch 145 closes, the electrical charge stored in the initial energy storage node 159 flows as electrical current (i1) in a resonant circuit formed by the initial energy storage node 159, the inductor 158, and the additional energy storage node 154. FIG. 1D shows an example of the current (i1) and a current (i2) as a function of time. The electrical current (i1) has a temporal width (w1), and a magnitude h1. The electrical current (i2) has a temporal width (w2) and a magnitude h2. The temporal width w1 is determined by the relative impedance values of the inductor 158, the initial energy storage node 159, and the additional energy storage node 154. For example, the temporal width w1 of the current (i1) and may be about 5 microseconds (s). The temporal width w2 is determined by the relative impedance values of the additional energy storage node 154, the magnetic switch 153, and a peaking capacitor 146. The temporal with w2 may be, for example 500 nanoseconds (ns).

The current (i1) flows out of the additional energy storage node 154, and the absolute value of the voltage across the additional energy storage node 154 increases. Although most of the current i1 flows out of the additional energy storage node 154, leakage current iL also flows in the magnetic switch 153. The current that flows in the magnetic switch 153 is shown as the current i2 in FIG. 1D. The leakage current iL causes the magnetization of the core 151 to increase along a path 164 (FIG. 1C) from an initial operating point 163, and the core 151 is no longer in the reverse saturation region 161.

The leakage current iL continues to flow into the magnetic switch 153, and the magnetization of the core 151 continues to increase along the path 164 until reaching the forward saturation region 162. When in the forward saturation region 162, the impedance of the core 151 is nearly zero. At this point, the magnetic switch 153 has a lower impedance than the inductor 158. The electrical energy stored in the additional energy storage node 154 flows through the magnetic switch 153 as current (shown as i2 in FIG. 1D) and accumulates in the peaking capacitor 146. This forms a potential difference across the peaking capacitor 146. The capacitor 146 is in parallel with electrodes 113a and 113b (which together form the excitation mechanism 113). Thus, the potential difference across the capacitor 146 is also formed between the electrodes 113a and 113b. This potential difference across the electrodes 113a and 113b is the excitation pulse 155 that excites the gain medium 119 and the discharge chamber 115 (FIG. 1A) emits an optical pulse (a pulse of the light beam 116).

The impedance of the magnetic switch 153 remains small until the current i2 is lower than a threshold current value that is determined by the coercivity (H_{c}) of the material of the magnetic switch 153. When the current i2 has passed through the magnetic switch 153, the current i2 no longer applies a magnetic field to the core 151 and the operating point moves along a path 166 to an operating point 167. Due to the magnetic properties of the material of the magnetic switch 153, the path 166 is not the same as the path 164.

As noted above, the excitation pulse 155 is produced by current that flows through the magnetic switch 153 when the switch 153 is in a low-impedance state (for example, the forward saturation region 162). Moreover, the operating point of the magnetic switch 153 is affected by the absolute value of the voltage across the additional energy storage node 154. Accordingly, the amount of voltage that is present at the additional energy storage node 154 at the beginning of a pulse-production cycle affects the amount of time required to reach the forward saturation region 162 and thus also affects the amount of time required to produce the electrical pulse 155.

The amount of voltage at the additional energy storage node 154 is not necessarily zero at the beginning of each electrical pulse-generation cycle and is not necessarily the same at the beginning of each electrical pulse-generation cycle. Operating conditions in the system 100 may affect the amount of voltage that is across the additional energy storage node 154 at the beginning of an electrical pulse-generation cycle. For example, reflections of the electrical pulse 155 may create a residual voltage that remains across the additional energy storage node 154 prior to the beginning of the next electrical pulse-generation cycle, and the amount of this residual voltage depends on the magnitude of the reflection. The magnitude of the reflection varies based on the temperature and/or pressure of the gain medium 119, the repetition rate and/or amplitude of the electrical pulse 155, and/or the temperature of the magnetic core 151, all of which may vary during operation of the system 100.

Accordingly, the voltage across the additional energy storage node 154 at the beginning of an electrical pulse-generation cycle may vary during operation of the system 100. The electronic module 170 controls the voltage at the additional energy storage node 154, thereby ensuring that the timing of the production of the electrical pulse 155 is more controlled, consistent, and/or predictable.

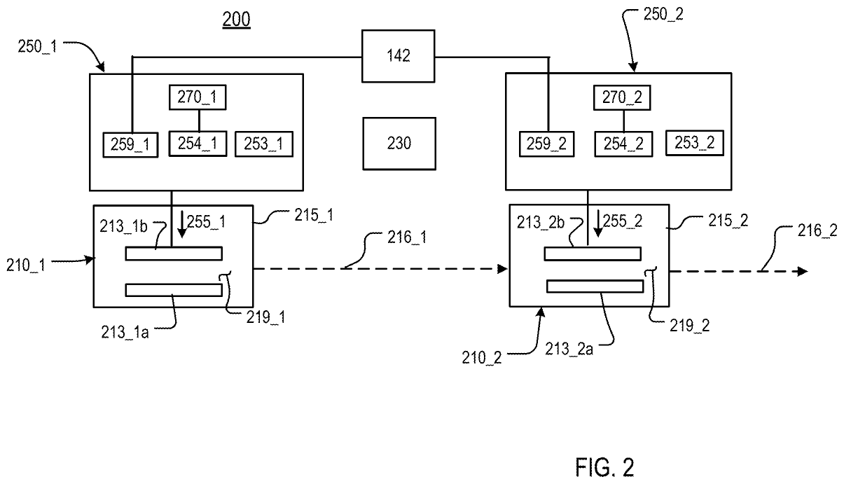

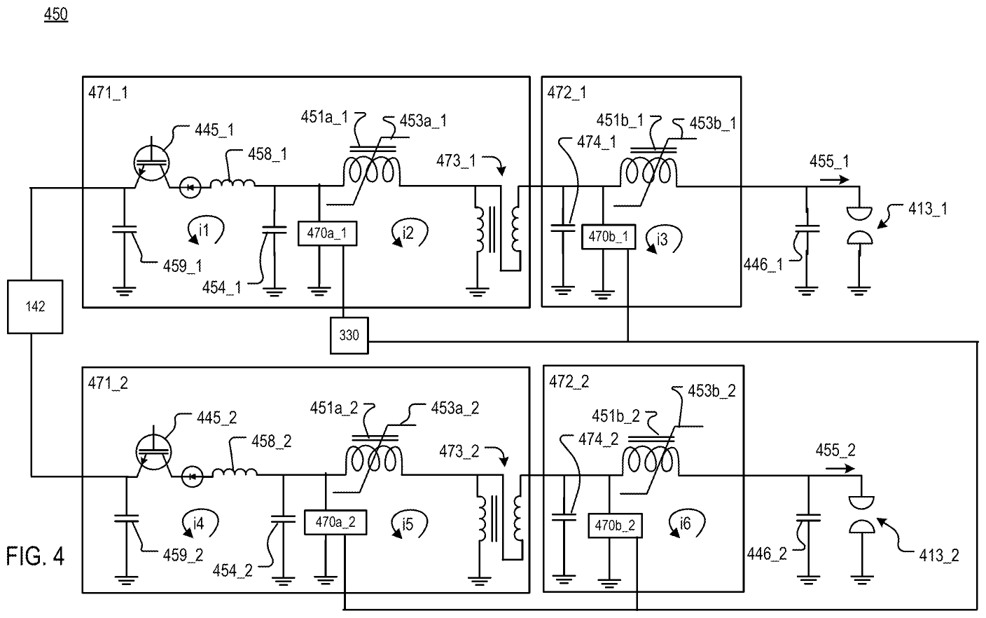

Furthermore, controlling the voltage across the additional energy storage node 154 also improves the burst mode performance of the optical source 110. When operating in burst mode, the light beam 116 produced by the optical source 110 includes bursts of pulses of light separated by periods of time that do not include light pulses. Each burst may include, hundreds, thousands, tens of thousands, or more pulses of light. The pulses of light within a burst of pulses have a repetition rate that suits the application. For example, the pulses of light within a burst may have a repetition rate of 1000 Hertz (Hz) to 6000 Hz, or a repetition rate of greater than 6,000 Hz. The period between the bursts has a temporal duration that is much longer than the time between two consecutive pulses in a burst. For example, the time between the end of one burst of pulses and the next burst of pulses may be hundreds or thousands of times longer than the time between two consecutive pulses within the burst. At the beginning of a burst, transient effects within the discharge chamber 115 (such as a changes in temperature and pressure of the gain medium 119 and switching effects caused by the switching network 150) cause the amount of optical energy in the first few pulses (for example, the first 100 or 200 pulses) to vary dramatically. Additionally, in a multi-stage system (such as shown in FIG. 2 and FIG. 4), the timing differences between the various stages tend to be more significant at the beginning of the burst. Moreover, the properties of the transient varies based on operating characteristics such as, for example, voltage applied to the excitation mechanism 113, repetition rate, and the pressure of the gain medium 119. By controlling the voltage across the additional energy storage node 154 (and thereby more finely controlling the magnetization of the core 151), the burst transient effects may be reduced.

The schematic shown in FIG. 1B is provided as an example, and other implementations are possible. For example, the example of the pulse-generating network 152 includes only one magnetic switch; and the resonant circuit formed by the additional energy storage node 154, the magnetic switch 153, and the peaking capacitor 146 is a single magnetic compression stage. However, in other implementations, the pulse-generating network 152 includes additional magnetic compression stages. For example, the pulse-generating network 152 may include more than one magnetic switch and more than one magnetic compression stage. These additional magnetic compression stages are placed in the pulse-generation circuit such that the peaking capacitor 146 remains in parallel with the electrodes 113a and 113b. FIG. 4 shows an example of a switching network 450 that includes more than one magnetic compression stage.

Furthermore, the system 100 may include more than one electronic module, and the other electronic modules may or may not be identical to the electronic module 170. For example, one or more of the additional magnetic compression stages may be electrically connected to an electronic module. Additionally, an electronic module may be electrically connected to the initial energy storage node 159.

Moreover, any variation of a multi-stage magnetic compression circuit may be used. For example, various components of the magnetic compression stages (for example, values of capacitor and inductance components) may be selected such that the current and voltage pulse produced at the peaking capacitor 146 has a shorter duration and larger amplitude than the voltage and current produced in the other stages. Further, the pulse-generation network 152 may include other components such as, for example, diodes and one or more voltage transformers. For example, the pulse-generation network 152 may include a step-up voltage transformer in parallel with the peaking capacitor 146. The step-up transformer increases the voltage across the peaking capacitor 146 and thereby generates an electrical pulse with a greater voltage magnitude. An example of a step-up transformer is shown in FIG. 4. Regardless of the specific configuration of the pulse-generation network 152, the electronic module 170 is used to control the voltage at one or more energy storage nodes that do not directly receive electrical charge from the charger 142.

Additionally, in the example shown in FIG. 1B, the high-voltage power supply 141 provides a voltage having a negative polarity such that the voltage at the output node 133 is negative relative to ground. However, in other implementations, the high-voltage power supply 141 provides a voltage having positive polarity such that the voltage at the output node 133 is positive relative to ground. In implementations in which the polarity of the high-voltage power supply 141 is positive, the currents (i1) and (i2) flow in the opposite direction than what is shown in FIG. 1B.

FIG. 2 is a block diagram of a system 200. The system 200 includes a two-stage laser system 210. The two-stage laser system that includes a first discharge chamber 2151, which produces a pulsed seed light beam 2161, and a second discharge chamber 2152, which amplifies the pulsed seed light beam 216_1 to produce an amplified pulsed light beam 216_2. The first discharge chamber 215_1 encloses electrodes 213_1a and 213_1b and a gaseous gain medium 219_1, and the second discharge chamber 215_2 encloses electrodes 213_2a and 213_2b and a gaseous gain medium 219_2.

The system 200 also includes switching networks 250_1 and 2502, each of which is similar to the switching network 150 (FIG. 1A). The switching networks 250_1 and 250_2 include respective magnetic switches 253_1 and 253_2 (each of which includes a magnetic core). The switching network 250_1 also includes an initial energy storage node 2591, an additional energy storage node 254_1, and an electronic module 270_1 that is electrically connected to the additional energy storage node 254_1. The switching network 250_2 includes an initial energy storage node 2592, an additional energy storage node 254_2, and an electronic module 270_2 that is electrically connected to the additional energy storage node 254_2.

The electronic module 270_1 controls the voltage across the additional energy storage node 254_1. The electronic module 270_2 controls the voltage across the additional energy storage node 254_2. In some implementations, the electronic module 270_1 and the electronic module 270_2 are configured to control the difference between the voltage across the additional energy storage node 254_1 and the voltage across the additional energy storage node 254_2. For example, the electronic module 270_1 and 270_2 may be configured to act to reduce the difference between the voltages or to make the voltages the same.

The system 200 also includes a control system 230 that is configured to trigger the electronic module 270_1 and/or the electronic module 270_2 into an active state in which the modules 270_1 and 270_2 control the voltage at the additional energy storage node 254_1 and/or the voltage at the additional energy storage node 254_2.

The switching network 250_1 produces an electrical pulse 2551, and the switching network 250_2 produces an electrical pulse 255_2. The electrical pulse 255_1 generates a potential difference between the electrodes 213_1a and 213_1b that is sufficient to excite atoms, ions, and/or molecules in the gain medium 219_1 to create population inversion in the gain medium 219_1 and a pulse of the seed light beam 216_1. The pulse of the seed light beam 216_1 enters the discharge chamber 215_2. The electrical pulse 255_2 is provided to the electrode 213_2b and a potential difference is formed between the electrode 213_2b and the electrode 213_2a. The potential difference is sufficient to excite atoms, ions, and/or molecules in the gain medium 219_2 to create population inversion in the gain medium 219_2. The excited gain medium 219_2 in the discharge chamber 2152 amplifies the seed light beam 216_1 and emits the amplified light beam 216_2.

Thus, the discharge chambers 215-1 and 215_2 work together to produce the amplified light beam 216_2. It is therefore desirable to maintain control over the relative timing between the electrical pulses 255_1 and 255_2 so that the timing of the excitation of the gain mediums 219_1 and 219_2 is properly coordinated for the application. For example, the gain medium 219_2 may be expected to be excited at the same time as the gain medium 219_1 or at a specified time after the gain medium 219_1 is excited. A deviation from the expected timing or coordination between excitation of the media 219_1 and 219_2 is referred to as a timing error. A timing error generally leads to reduced performance for the system 200. For example, an extreme or large timing error may result in a pulse of the seed light beam 216_1 passing through the discharge chamber 215_2 when the gain medium 219_2 is not excited. In this situation, the pulse of the seed light beam 216_1 will not be amplified. Smaller and less extreme timing errors also may lead to sub-optimal performance. For example, a relatively small timing error may lead to variations in the bandwidth and/or energy of the various pulses of the amplified light beam 216_2. Moreover, a small voltage difference between the additional energy storage node 254_1 and 254_2 (for example, a difference of about 0.1%) may result in a relatively large timing error (for example, +/−2 nanoseconds (ns)). By controlling the amount of voltage at the additional energy storage nodes 254_1 and 254_2, the electronic modules 270_1 and 270_2 helps to ensure that the timing of the excitation of the discharge chamber 215_1 and the discharge chamber 215_2 is controlled, and timing errors are eliminated, mitigated, or reduced.

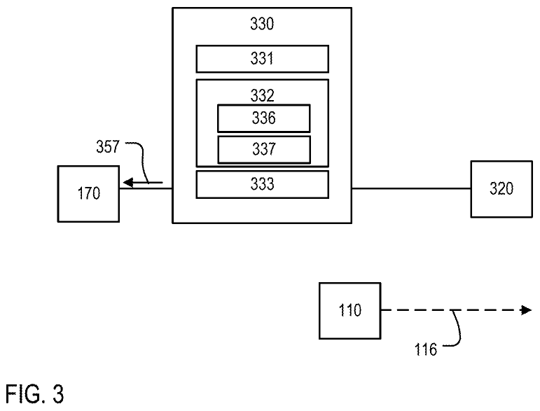

FIG. 3 is a block diagram of a control system 330. The control system 330 may be used as the control system 230 (FIG. 2). The control system 330 includes an electronic processing module 331, an electronic storage module 332, and an input/output (I/O) interface 333.

The electronic processing module 331 includes one or more processors suitable for the execution of a computer program such as a general or special purpose microprocessor, and any one or more processors of any kind of digital computer. Generally, an electronic processor receives instructions and data from a read-only memory, a random access memory (RAM), or both. The electronic processing module 331 may include any type of electronic processor. The electronic processor or processors of the electronic processing module 331 execute instructions and access data stored on the electronic storage 332. The electronic processor or processors are also capable of writing data to the electronic storage 332.

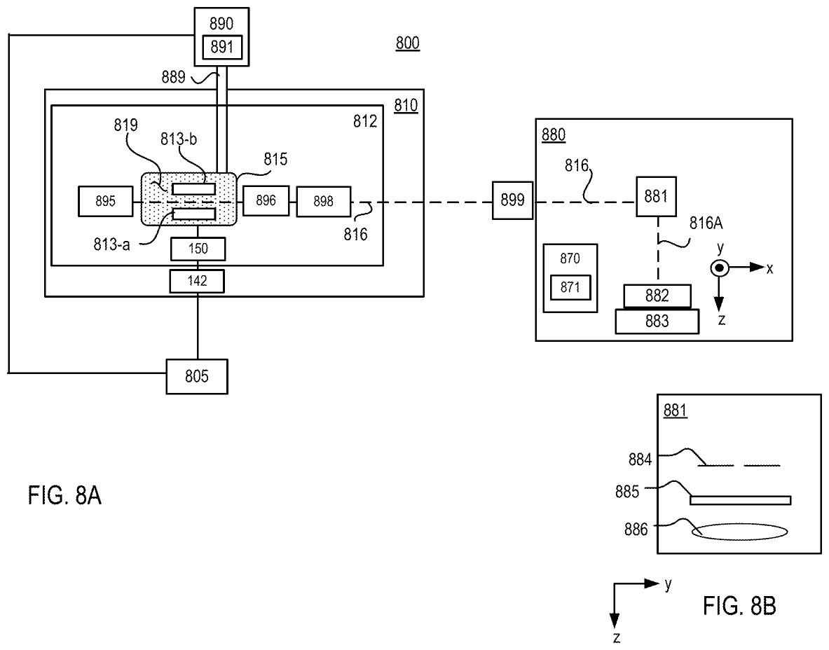

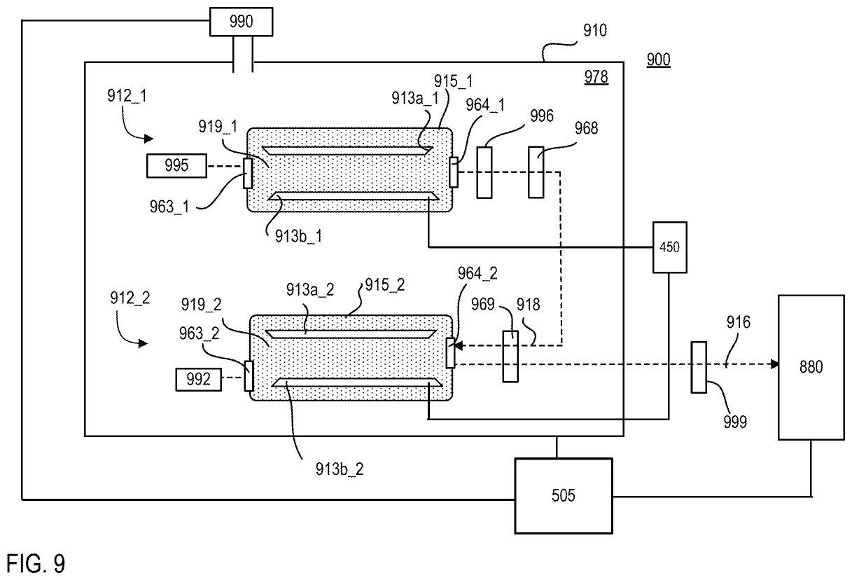

The electronic storage 332 is any type of computer-readable or machine-readable medium. For example, the electronic storage 332 may be volatile memory, such as RAM, or non-volatile memory. In some implementations, the electronic storage 332 includes non-volatile and volatile portions or components. The electronic storage 332 may store data and information that is used in the operation of the control system 330. The electronic storage 332 also may store instructions (for example, in the form of a computer program) that cause the control system 330 to interact with components and subsystems in the switching network 150 (including the electronic module 170), the optical source 110, and/or a scanner apparatus (such as the scanner apparatus 880 shown in FIGS. 8A and 9).

The electronic storage 332 also stores instructions and/or electronic elements that implement a control module 336. The control module 336 generates a command signal 357 that is sufficient to trigger the electronic module 170 such that the electronic module 170 controls or adjusts the voltage across the additional energy storage node 154. For example, the control module 336 may include a voltage source. In these implementations, the instructions control the voltage source to produce a voltage signal, and the command signal 357 is a voltage signal that causes a transistor in the electronic module 170 to change state. Moreover, the control module 336 is configured to control the duration at which the transistor in the electronic module 170 stays in a particular state. The magnitude and timing of the voltage signal may be pre-programmed and stored on the electronic storage 332.

The system 300 also includes a monitoring module 320. The monitoring module 320 is any type of device that is capable of monitoring the operating characteristics of the system 100. For example, the monitoring module 320 may include optical and/or electronic components that measure operating characteristics such as repetition rate or voltage applied to the excitation mechanism 113. In some implementations, the monitoring module 320 accesses the values of the operating characteristics from the optical source 110, the switching network 150, and/or the electrical charger 142. In these implementations, the monitoring module 320 does not directly measure the operating characteristics. For example, the monitoring module 320 may obtain readings from other sensors (such as temperature or pressure sensors or pulse timing-error sensors) that perform direct measurements and/or may obtain set values that are set at the time of manufacture and are stored in memory in a particular sub-system of the source 110.

In some implementations, the information collected by the monitoring module 320 is used to determine when to trigger the electronic module 170. For example, the monitoring module 320 may measure the repetition rate of the light beam 116, and the control system 330 may trigger the electronic module 170 after a pre-specified number of light pulses are produced.

The electronic storage 332 also stores instructions that make up a laser command module 337. The laser command module 337 controls various aspects of the operation of the optical source 110 and/or the pulse-generating network 152. The laser command module 337 controls, for example, the state of the switches 148 and 145. In some implementations, the command module 337 starts a pulse-generation cycle by closing the switch 148 and then commands the switch 148 to open when a target voltage is achieved on the output node 134. The value of the target voltage may be stored on the electronic storage 322 and/or received from an operator or machine through the I/O interface 333. Other implementations are possible. For example, the laser command module 337 may be configured to trigger the switch 148 to close after the voltage across the capacitor 143 in the resonant charger 135 reaches the specified voltage or after a pre-determined amount of time has passed. The laser command module 337 triggers the switch 145 to close after the voltage across the capacitor 159 reaches a specified voltage. For example, in implementations in which the switches 148 and 145 are transistors, the laser command module 337 may control a voltage source that provides a voltage to the gate of the transistors, where the voltage is sufficient to cause the transistors to change state and conduct current. The specified voltage and pre-determined time are stored on the electronic storage 332.

The laser command module 337 also may control other aspects of the optical source 110, such as the repetition rate of the light beam 116. The laser command module 337 may control the various aspects based on a pre-programmed recipe that is also stored on the electronic storage 332 and/or is provided through the I/O interface 333.

The electronic storage 332 also may store various other parameters and values used in the operation of the optical source 110 and/or the pulse-generating network 152.

The I/O interface 333 is any kind of interface that allows the control system 330 to exchange data and signals with an operator, other devices (such as the monitoring module 320), and/or an automated process running on another electronic device. For example, in implementations in which rules or instructions stored on the electronic storage 332 may be edited, the edits may be made through the I/O interface 333. In another example, in some implementations, the operator or user of the system 100 is able to use the I/O interface 333 to cause the control module 336 to trigger the electronic module 170. The I/O interface 333 may include one or more of a visual display, a keyboard, and a communications interface, such as a parallel port, a Universal Serial Bus (USB) connection, and/or any type of network interface, such as, for example, Ethernet. The I/O interface 333 also may allow communication without physical contact through, for example, an IEEE 802.11, Bluetooth, or a near-field communication (NFC) connection.

FIG. 4 is a schematic of a switching network 450. The switching network 450 is an example of a switching network that is used with a two-stage optical system such as the optical systems shown in FIG. 2 and FIG. 9. The switching network 450 also includes electronic modules 470a_1, 470b_1, 470a2, and 470b_2, which are used to control voltage levels at various energy storage nodes (capacitors in the example of FIG. 4). The switching network 450 is used with the electrical charger 142 and the control system 330. The switching network 450 includes a first commutator 471_1 and a first compression head 4721, which produce an electrical pulse 455_1 that creates a potential difference across a first set of separated electrodes 413_1. The electrodes 413_1 are enclosed in a first discharge chamber that also includes a first gaseous gain medium. The switching network 450 also includes a second commutator 471_2 and a second compression head 4722, which produce an electrical pulse 455_2 that creates a potential difference across a second set of separated electrodes 413_2. The separated electrodes 413_2 are enclosed in a second discharge chamber that also encloses a gaseous gain medium.

The electrical charger 142 is electrically connected to a capacitor 459_1 and to an emitter of a switch 445_1. In this example, the switch 445_1 is an insulated bi-polar gate transistor (IGBT). The gate of the switch 445_1 is coupled to a voltage source (not shown). The electrical charger 142 is triggered on, and current flows to the capacitor 459_1. When the voltage across the capacitor 459_1 meets a specified voltage, the switch 4451 is triggered to change to an on state and current flows through the switch 445_1 and an inductor 458_1 and accumulates on a capacitor 454_1. Some of the current i1 also leaks into a magnetic switch 453a_1 and the magnetization of a core 451a_1 increases until reaching a forward saturation point. The electrical energy in the capacitor 454_1 flows through the magnetic switch 453a_1, is transformed into a higher voltage by a step-up voltage transformer 473_1 and accumulates on a capacitor 474_1. Although the implementation shown in FIG. 4 shows the step-up voltage transformer 473_1, any device capable of increasing output voltage in relation to the input voltage may be used. A magnetic core 451b_1 enters the forward saturation region 162. The electrical energy stored in the capacitor 474_1 flows through the magnetic switch 453b_1 and accumulates on a peaking capacitor 446_1 and creates a potential difference across the first pair of electrodes 413_1. The increase in voltage provided by the step-up voltage transformer 473_1 allows a relatively large voltage to form across the peaking capacitor 446_1. For example, in an implementation in which the electrical charger 142 provides about 800 V DC at an output node that is electrically connected to the capacitor 4591, the absolute value of the voltage on the peaking capacitor 446_1 may be about 20 kV.

The second commutator 471_2 and the second compression head 472_2 operate in a similar manner.

The switching network 450 also includes the electronic modules 470a_1, 470b_1, 470a_2, and 470b_2. The electronic module 470a_1 is electrically connected in parallel with the capacitor 454_1. The electronic module 470b_1 is electrically connected in parallel with the capacitor 474_1. The electronic module 470a_2 is electrically connected in parallel with the capacitor 454_2. The electronic module 470b_2 is electrically connected in parallel with the capacitor 474_2. Each of the electronic modules 470a 1, 470b 1, 470a2, and 470b_2 includes a controllable electronic network. The controllable electronic network may include, for example, one or more transistors or other controllable electronic devices. The electronic module 470a_1 controls the voltage across the capacitor 454_1. The electronic module 470b_1 controls the voltage across the capacitor 474_1. The electronic module 470a_2 controls the voltage across the capacitor 454_2. The electronic module 470b_2 controls the voltage across the capacitor 474_2.

The switching network 450 may include additional elements that are not shown in FIG. 4. For example, the switching network 450 may include an electronic module connected to the initial energy storage nodes (the capacitor 459_1 and the capacitor 459_2 in this example). The electronic module may include a diode. For an implementation based on a negative polarity charge on the initial energy storage nodes (such as shown in FIG. 4), the diodes are arranged with the anodes connected to the initial energy storage nodes. For implementations based on a positive polarity charge on the initial energy storage nodes, the diodes are arranged with the cathodes connected to the initial energy storage nodes. These electronic modules act to control the voltage at the initial energy storage nodes.

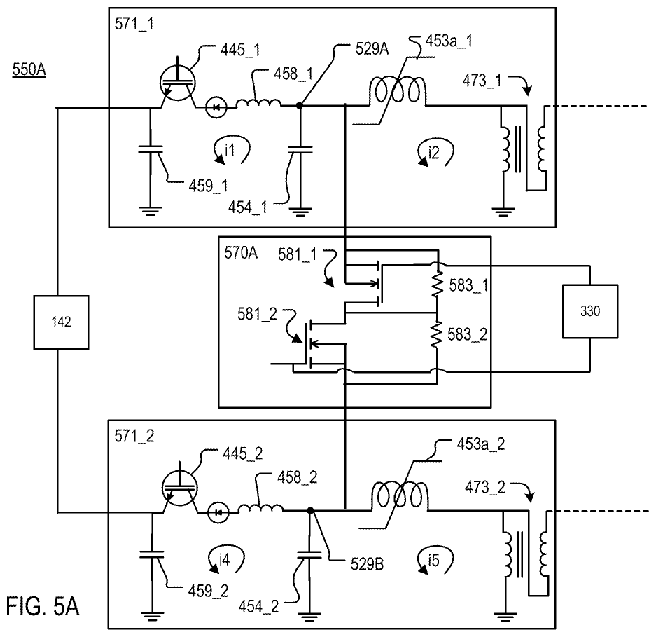

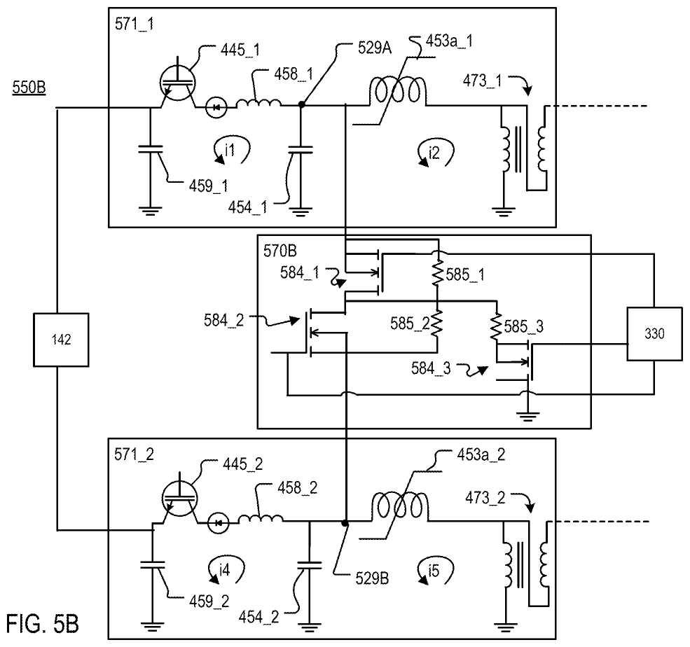

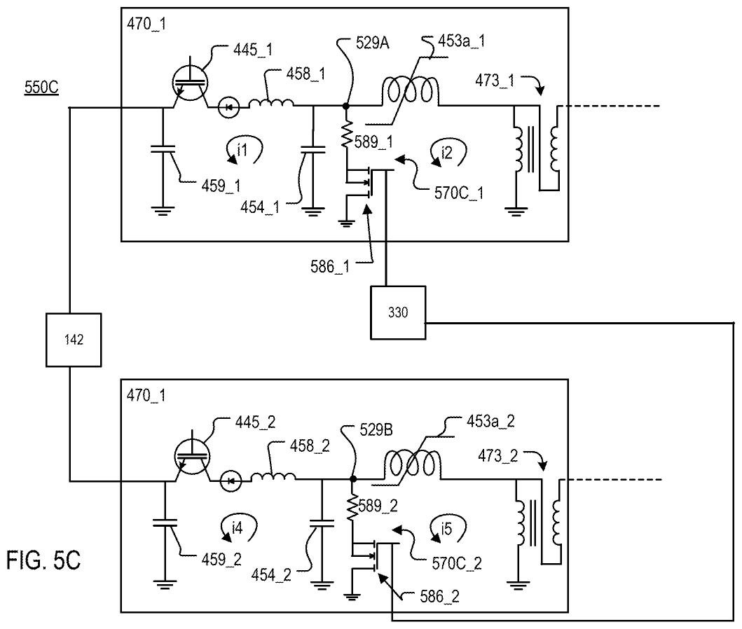

FIGS. 5A-5C are schematics that include examples of electronic modules. Referring to FIG. 5A, a switching network 550A includes a first commutator 571_1 and a second commutator 571_2. The switching network 550A may include additional magnetic compression stages. For example, the switching network 550A may include the first and second compression heads 472_1 and 4722 (FIG. 4). The first and second commutators 571_1 and 571_2 are the same as the first and second commutators 471_1 and 471_2 (FIG. 4), except the first commutator 571_1 does not include the electronic module 470_1 and second commutator 571_1 does not include the electronic module 470_2. Instead, the switching network 550A includes an electronic module 570A, which is configured to control the voltages at a node 529A and a node 529B. The voltage at the node 529A is the voltage across the capacitor 454_1 and the voltage at the node 529B is the voltage across the capacitor 454_2. For example, the electronic module 570A may be configured to reduce or eliminate a voltage difference between the node 529A and the node 529B. In other words, the electronic module 570A may be configured to make the voltages at the node 529A and 529B the same.

The electronic module 570A includes a first high-voltage switch 5811, a second high-voltage switch 581_2, and resistors 583_1 and 583_2. The resistors 583_1 and 5832 may have the same resistance value. The first and second high-voltage switches 581_1 and 581_2 are any type of controllable switch that includes at least an ON state in which the switch conducts current and an OFF state in which the switch does not conduct current. The switches 581_1 and 581_2 may be transistors, such as, for example, metal-oxide field effect transistors (MOSFETs), bi-polar junction transistors (BJTs), or IGBTs. In the example shown in FIG. 5A, the each high-voltage switch 581_1 and 581_2 is a MOSFET. The source of the switch 581_1 is electrically connected to the node 529A. The gate of the switch 581_1 is electrically connected to the control system 330. The drain of the switch 581_1 is electrically connected to the drain of the switch 581_2. The gate of the switch 581_2 is electrically connected to the control system 300. The source of the switch 581_2 is electrically connected to the node 529B. The resistor 5831 is in parallel with the switch 581_1, and the resistor 583_2 is in parallel with the switch 581_2.

The electronic module 570A is configured to provide low-impedance shorting of the nodes 529A and 529B when the switches 581_1 and 581_2 are in the ON state and a high-impedance connection between the nodes 529A and 529B when the switches are in the OFF state. When the switches 581_1 and 581_2 are OFF, substantially no electrical current flows in the switches 581_1 and 581_2, and the commutators 571_1 and 571_2 are only electrically connected through the resistors 583_1 and 583_2. The resistors 583_1 and 583_2 provide a high-impedance path between the nodes 529A and 529B. When the switches 581_1 and 581_2 are ON, electrical current flows from the node 529A and in the switch 581_1, and from the node 529B and in the switch 581_2. This causes the voltages at the nodes 529A and 529B to balance or move toward the same voltage value, thereby reducing the magnitude of the voltage difference between the nodes 529A and 529B and/or making the voltage at the nodes 529A and 529B the same.

The electronic module 570A is in an active state or is enabled when the switches 581_1 and 581_2 are ON. The electronic module 570B is in an inactive state or is disabled when the switches 581_1 and 581_2 are OFF. The control system 330 controls the state of the switches 581_1 and 581_2 with trigger signals. For example, to turn the switches 581_1 and 581_2 ON, the control system 330 provides a voltage signal to the gate of the switch 581_1 and to the gate of the switch 581_2. The characteristics (for example, amplitude and polarity) of the voltage depend on the specifications of the switch, but the trigger voltage is sufficient to cause the switches 581_1 and 581_2 to transition to the ON state. The control system 330 is also configured to turn the switches 581_1 and 581_2 OFF. For example, in implementations in which the switches 581_1 and 581_2 are MOSFETs, the control system 330 provides a trigger signal to the gate of each switch 581_1 and 581_2 that is less than the voltage of the source.

FIG. 5B is a schematic of a switching network 550B. The switching network 550B is the same as the switching network 550A, except the switching network 550B includes an electronic module 570B instead of the electronic module 570A. The electronic module 570B includes controllable switches 584_1, 584_2, and 584_3. The electronic module 570A is configured to provide low-impedance path to ground when the switches 584_1, 581_2, and 581_3 are in the ON state and a high impedance when the switches are in the OFF state. The nodes 529A and 529B are electrically connected only through the resistors 585_1 and 585_2 when the electronic module 570B is in the inactive state.

The high-voltage switches 584_1, 584_2, and 584_3 are any type of controllable switch that includes at least an ON state in which the switch provides a low-impedance path that conducts current and an OFF state in which the switch provides a high-impedance that does not conductor current. The switches 584_1, 584_2, and 584_3 may be transistors, such as, for example, metal-oxide field effect transistors (MOSFETs), bi-polar junction transistors (BJTs), or IGBTs. In the example shown in FIG. 5A, the each high-voltage switch 584_1, 584_2, and 584_3 is a MOSFET. The source of the switch 584_1 is electrically connected to the node 529A. The gate of the switch 584_1 is electrically connected to the control system 330. The drain of the switch 584_1 is electrically connected to the drain of the switch 584_2. The gate of the switch 584_2 is electrically connected to the control system 300. The source of the switch 584_2 is electrically connected to the node 529B. A resistor 585_1 is in parallel with the switch 581_1, and a resistor 585_2 is in parallel with the switch 581_2. The resistors 585_1 and 585_2 may have the same resistance value.

The electronic module 570B also includes the switch 584_3 and the resistor 585_3. The gate of the switch 584_3 is connected to the control system 330. The source of the switch 584_3 is electrically connected between the resistors 585_1 and 585_2. The drain of the switch 584_3 is connected to ground. The resistor 585_3 is connected between the resistors 585_1 and 585_2 and is also electrically connected in series with the source of the switch 584_3. The electronic module 570B may be implemented without the resistor 585. Regardless of whether or not the electronic module 570B includes the series resistor 585_3, the switch 584_3 provides resistance to the ground path when the switch 584_3 is in the ON state. On the other hand, including the series resistor 585_3 allows for greater control of the impedance of the ground path.

The electronic module 570B is in an active state or is enabled when the switches 584_1, 584_2, and 584_3 are ON. The electronic module 570B is in an inactive state or is disabled when the switches 584_1, 584_2, and 584_3 are OFF. The electronic module 570B provides a low-impedance path between each node 529A and 529B and ground when the electronic module 570B is active. When the electronic module 570B is in the active state, electrical charge on the node 529A and on the node 529B is discharged to ground through the resistor 585_3 and the switch 584_3. This causes the voltage difference between the nodes 529A and 529B to be reduced or eliminated and the voltage potential at each of the nodes 529A and 529B is reduced or eliminated. When the electronic module 570B is in the inactive state, the electronic module 570B forms a high-impedance path between the nodes 529A and 529B such that the electronic module 570B has substantially no effect on the voltages at the node 529A or the node 529B.

The electronic modules 570A (FIG. 5A) and 570B (FIG. 5B) are external modules that are connected to both of the commutators 571_1 and 571_2. FIG. 5C shows an example of internal electronic modules 570C_1 and 570C_2. The internal electronic module 570C_1 or 570C_2 may be used as the electronic module 170 or 270.

The electronic module 570C_1 includes a resistor 589_1 and a switch 586_1 that is in series with the resistor 589_1. The switch 5861 is any type of controllable switch and may be, for example, a transistor. In the example of FIG. 5C, the switch 586_1 is a MOSFET. The resistor 589_1 is electrically connected to the node 529A and to the source of the switch 586_1. The electronic module 570C_2 includes a resistor 589_2 and a switch 586_2 that is in series with the resistor 589_2. The switch 586_2 is any type of controllable switch and may be, for example, a transistor. In the example of FIG. 5C, the switch 586_2 is a MOSFET. The resistor 589_2 is electrically connected to the node 529B and to the source of the switch 586_2. The drain of each of the switches 586_1 and 586_2 is connected to ground. The gate of each of the switches 586_1 and 586_2 is connected to the control system 330. The control system 330 controls the state of the switches 586_1 and 586_2 by providing trigger signals to the respective gates. That is, the control system 330 determines whether the switch 586_1 is ON or OFF and whether the switch 586_2 is ON or OFF.

When the switch 586_1 is ON, the electronic module 570C_1 is in an active state or is enabled, and electrical charge on the node 529A is discharged to ground through the electronic module 570C_1. When the switch 586_1 is OFF, the electronic module 570C_1 presents a high impedance to the node 529A and does not affect the voltage at the node 529A. Similarly, when the switch 586_2 is ON, the electronic module 570C_2 is in an active state and discharged electrical charge on the node 529B to ground. When the switch 586_2 is OFF, the electronic module 570C_2 presents a high impedance to the node 529B and does not affect the voltage at the node 529B.

In the examples shown in FIGS. 5A-5C, the electronic modules 570A, 570B, and 570C are used to control the voltage at nodes 529A and 529B. However, other implementations are possible. For example, the electronic modules 570A, 570B, and 570C may be connected to other energy storage nodes such as the step up transformer 473_1 and 4732 (FIG. 4). Moreover, a system may include more than one of the electronic modules 570A, 570B, 570C_1 and/or 570C_2. For example, a system may be implemented with the electronic module 570A connected to the nodes 529A and 529B and a second instance of the electronic module 570A connected to the capacitors 474_1 and 474_2.

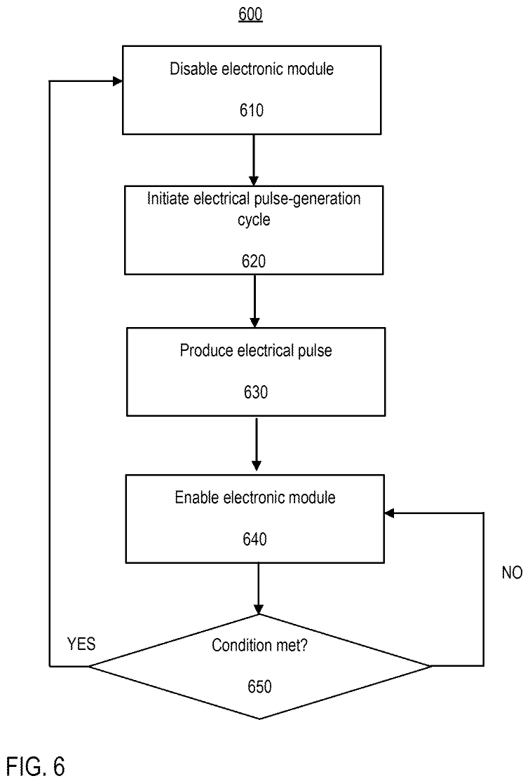

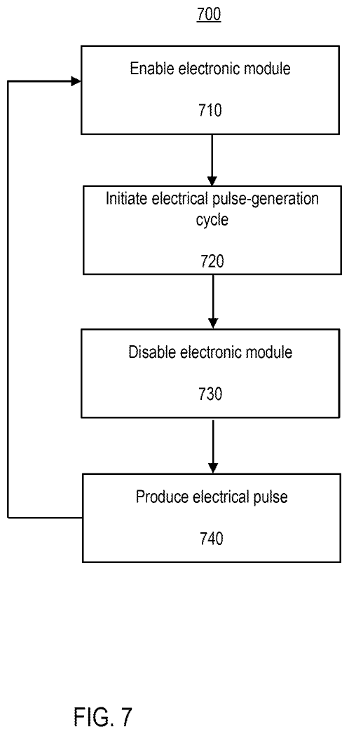

FIGS. 6 and 7 are flow charts of example processes 600 and 700, respectively, for operating a switching network that includes an electronic module that controls a voltage at an energy storage node. For example, the processes 600 and 700 may be used with the switching networks 150, 250, 450, 550A, 550B, or 550C. The processes 600 and 700 may be implemented as a collection of executable instructions or a computer program that is stored on the electronic storage 332 and performed by the electronic processing module 331 of the control system 330. The process 600 is discussed with respect to the switching network 550B (FIG. 5B) and the control system 300. However, the process 600 may be performed with other switching networks that include an electronic module at one or more energy storage nodes.

Referring to FIG. 6, the electronic module 570B is disabled (610). To disable the electronic module 570B, the command module 336 (FIG. 3) of the control system issues an instance of the command signal 357 to the gates of each switch 584_1, 584_2, and 584_3. The command signal 357 is a voltage signal that is sufficient to place each switch 584_1, 584_2, and 584_3 in the OFF state. The characteristics of the command signal 357 depend on the specification of the switches 584_1, 584_2, and 584_3. For example, if the switches 584_1, 584_2, and 584_3 are p-channel MOSFET, the command signal 357 is a voltage signal that makes the voltage between the gate and the source greater than zero. With the electronic module 570B disabled, the nodes 529A and 529B are electrically separated from each other.

An electrical pulse-generation cycle is initiated (620). As discussed above, the electrical pulse-generation cycle results in a potential difference forming across the electrodes 413_1 and 413_2 (FIG. 4). During the electrical pulse-generation cycle, the electronic module 570B is disabled. Thus, the electronic module 570B does not have an effect on the electrical charge that accumulates in the energy storage node 454_1 or the energy storage node 454_2. Additionally, the electronic module 570B does not affect the discharge of the accumulated electrical charge into the saturable reactors 453a_1 and 453a_2. The electrical pulses 455_1 and 455_2 are generated (630).

The control system 330 enables the electronic module 570B (640). For example, the control system 330 may enable the electronic module 570B after the electrical pulses 455_1 and 455_2 are generated and before subsequent electrical pulses are generated such that accumulated electrical charge is removed from the energy storage nodes 529A and 529B before the subsequent electrical pulses are generated. The control system 330 enables the electronic module 570B by triggering the switches 584_1, 584_2, and 584_3 to the ON state. The electronic module 570B may provide a voltage signal to the gate of each switch 584_1, 584_2, and 584_3 that has characteristics sufficient to turn the switches 584_1, 584_2, and 584_3 ON. For example, if the switches 584_1, 584_2, and 584_3 are p-channel MOSFETs, the control system 330 provides a voltage signal to the gates of each switch 584_1, 584_2, and 584_3 such that the voltage between the gate and the source is less than zero. Enabling the electronic module 570B dissipates electrical charge from the nodes 529A and 529B and causes the nodes 529A and 529B to have the same voltages.

After the control system 300 enables the electronic module 570B at (640), the process 600 may end or returns to (610). In some implementations, the process 650 includes a condition check (650). In these implementations, the control system 330 determines whether or not a pre-set condition has been satisfied (650). If the pre-set condition has not been satisfied, the control system 330 does not interact with the electronic module 570B, and the electronic module 570B remains in the enabled state (such that the energy storage nodes 529A and 529B are electrically connected and electrical charge is dissipated from the nodes 529A and 529B) until the condition is satisfied. If the pre-set condition has been satisfied, the process 600 returns to (610), and the electronic module 570B is disabled (such that the energy storage nodes 529A and 529B are not electrically connected to each other).

In implementations that include the condition (650), the pre-set condition may be, for example, the completion of the production of the electrical pulses 455_1 and 455_2 and the resulting excitation of the electrodes 413a_1 and 413a_2, and 413b_1 and 413b_2. In these implementations, the process 600 returns to (610) only after the production of the electrical pulses 455_1 and 455_2 is complete. This pre-set condition ensures that the electronic module 570B does not interfere with the electrical pulse-generation cycle that produced the electrical pulses 455_1 and 455_2 and that residual electrical charge that may arise on the nodes 529A and 529B due to reflections of the respective electrical pulses 455_1 and 455_2 does not interfere with the next electrical pulse-generation cycle (because the electronic module 570B was enabled in (640) to dissipate electrical charge from the nodes 529A and 529B). In this way, the pre-set condition helps to ensure that the conditions at the energy storage node 529A and 529B are predictable and constant at the beginning of an electrical pulse-generation cycle.

Another example of the pre-set condition is a time interval. The time interval may be, for example, a fixed amount of time from when the electrical pulse-generation cycle begins, a fixed amount of time after the electronic module 570B is enabled, or a fixed amount of time after the excitation of the electrodes 413a_1 and 413a2, and/or the excitation of the electrodes 413b_1 and 413b_2. The time interval may be stored on the electronic storage 332.

The process 600 may be performed at the beginning of each electrical pulse-generation cycle. In these implementations, the process 600 is performed on a pulse-to-pulse basis and is performed for each pulse of light produced by a two-stage optical system that includes a first chamber that includes the electrodes 413a_1 and 413b_1 and a second chamber that includes the electrodes 413a_2 and 413b_2. In other words, in these implementations, the electronic module 570B is disabled (610) at the beginning of each pulse generation cycle and is enabled (640) after completion of each pulse generation cycle, and, if the process 600 includes the condition (650), the condition (650) is the completion of one pulse-generation cycle. In other implementations, the process 600 is performed before each burst of pulses produced by the two-stage optical system. In still other implementations, the process 600 is performed before some but not all optical pulses produced by the two-stage optical system.

Moreover, in some implementations, at start-up, initial use after installation or repair, at the beginning of a burst of optical pulses, or after any other relatively prolonged period of inactivity (and prolonged period since the most recent enabling of the electronic module 570B), the control system 330 may enable the electronic module 570B prior to disabling the electronic module 570B at (610) such that any residual voltage that may have accumulated on the nodes 529A and 529B during the inactivity is discharged prior to performing the process 600.

Referring to FIG. 7, the process 700 is another example of a process for operating a switching network. The process 700 is discussed with respect to the switching network 550A (FIG. 5A) and the control system 300. However, the process 700 may be performed with other switching networks that include an electronic module at one or more energy storage nodes.

The electronic module 570A is enabled (710) to balance the voltage on the nodes 529A and 529B. The electronic module 570A is enabled by the control system 330. For example, the control system 330 may provide a voltage signal to the gate of each switch 581_1 and 581_2 such that the switches 581_1 and 581_2 turn ON. Enabling the electronic module 570A reduces or eliminates the difference between the voltage at the node 529A and the voltage at the node 529B. An electrical pulse-generation cycle is initiated (720). The capacitors 454_1 and 454_2 accumulate electrical charge as discussed above with respect to FIG. 4. The electronic module 570A acts to balance or equalize the voltage at the nodes 529A and 529B while the capacitors 454_1 and 454_2 accumulate charge. The module 570A is disabled (730) before the saturable reactors 453a_1 and 453a_2 saturate, and before the capacitors 454_1 and 454_2 discharge their electrical energy. To disable the electronic module 570A, the control system 330 provides voltage signals to the gate of each of the switches 581_1 and 581_2 to turn the switches OFF. After the module 570A is disabled, the nodes 529A and 529B are electrically connected only through the resistors 583_1 and 583_2. The electrical pulses 455_1 and 455_2 are produced (740) as discussed above.

After the electrical pulses 455_1 and 455_2 are produced at (740), the process 700 returns to (710). The process 700 may be performed at the beginning of each electrical pulse-generation cycle. In these implementations, the process 700 is performed on a pulse-to-pulse basis and is performed for each pulse of light produced by a two-stage optical system that includes a first chamber that includes the electrodes 413a_1 and 413b_1 and a second chamber that includes the electrodes 413a_2 and 413b_2. In other implementations, the process 700 is performed before each burst of pulses produced by the two-stage optical system. In still other implementations, the process 700 is performed before some but not all optical pulses produced by the two-stage optical system.

The process 700 balances the voltages on the capacitors 454_1 and 454_2 before a pulse-generating cycle begins. Thus, if the voltages on the capacitors 454_1 and 454_2 are different before the pulse-generating cycle begins (for example, such voltage differences may result from the prior pulse), enabling the electronic module 570A balances the voltages on the capacitors 454_1 and 454_2 and mitigates any voltage error that may cause a timing error. Furthermore, by enabling the electronic module 570A before a pulse-generating cycle begins, any sources of voltage difference due to the charging circuit 135 (which is part of the electrical charger 142) are mitigated, and therefore the timing error is reduced or eliminated. Turn on time, difference in losses or voltage drops in the charging circuit 135 are examples of sources of voltage difference due to the charging circuit 135.

FIGS. 8A and 9 provide additional examples of systems that may use the techniques discussed above.

FIG. 8A is an example of a deep ultraviolet (DUV) optical system 800. The system 800 includes a light-generation module 810 that provides an exposure beam (or output light beam) 816 to a scanner apparatus 880. In the example of FIG. 8A, the light-generation module 810 is used with the switching network 150. A control system 805 is also coupled to the light-generation module 810 and to various components associated with the light-generation module 810.

The light-generation module 810 includes an optical oscillator 812. The optical oscillator 812 generates the output light beam 816. The optical oscillator 812 includes a discharge chamber 815, which encloses an excitation mechanism (a cathode 813-a and an anode 813-b). The discharge chamber 815 also contains a gaseous gain medium 819 (shown with light dotted shading in FIG. 8A). A potential difference between the cathode 813-a and the anode 813-b forms an electric field in the gaseous gain medium 819. The potential difference is generated by controlling the switching network 150 to generate a potential difference across the electrodes 813-a and 813-b. The potential difference forms an electric field, which provides energy to the gain medium 819 sufficient to cause a population inversion and to enable generation of a pulse of light via stimulated emission.

Repeated creation of such a potential difference forms a train of pulses, which are emitted as the light beam 816. The repetition rate of the pulsed light beam 816 is determined by the rate at which voltage is applied to the electrodes 813-a and 813-b. The repetition rate of the pulses may range, for example, between about 500 and 6,000 Hertz (Hz). Other repetition rates may be used, and the light-generation module 810 may be operated in a single-shot mode in which a single pulse of light is emitted. In some implementations, the repetition rate may be greater than 6,000 Hz, and may be, for example, 12,000 Hz or greater. Each pulse emitted from the optical oscillator 812 may have a pulse energy of, for example, approximately 1 milliJoule (mJ).

Moreover, the light beam 816 may include bursts of pulses of light separated by an interval of no light. The bursts may include hundreds or thousands of pulses of light. Within the burst, the pulses of light have a repetition rate determined by the rate at which the potential difference is formed across the electrodes 813-a and 813-b. The time between bursts is determined by the application and may be, for example, a hundred or a thousand times longer than the time between two consecutive pulses in the burst.

The gaseous gain medium 819 may be any gas suitable for producing a light beam at the wavelength, energy, and bandwidth required for the application. The gaseous gain medium 819 may include more than one type of gas, and the various gases are referred to as gas components. For an excimer source, the gaseous gain medium 819 may contain a noble gas (rare gas) such as, for example, argon, xenon, or krypton; or a halogen, such as, for example, fluorine or chlorine. In implementations in which a halogen is the gain medium, the gain medium also includes traces of xenon apart from a buffer gas, such as helium.

The gaseous gain medium 819 may be a gain medium that emits light in the deep ultraviolet (DUV) range. DUV light may include wavelengths from, for example, about 100 nanometers (nm) to about 400 nm. Specific examples of the gaseous gain medium 819 include argon fluoride (ArF), which emits light at a wavelength of about 193 nm, krypton fluoride (KrF), which emits light at a wavelength of about 248 nm, or xenon chloride (XeCl), which emits light at a wavelength of about 351 nm.

A resonator is formed between a spectral adjustment apparatus 895 on one side of the discharge chamber 815 and an output coupler 896 on a second side of the discharge chamber 815. The spectral adjustment apparatus 895 may include a diffractive optic such as, for example, a grating and/or a prism, that finely tunes the spectral output of the discharge chamber 815. The diffractive optic may be reflective or refractive. In some implementations, the spectral adjustment apparatus 895 includes a plurality of diffractive optical elements. For example, the spectral adjustment apparatus 895 may include four prisms, some of which are configured to control a center wavelength of the light beam 816 and others of which are configured to control a spectral bandwidth of the light beam 816.

The spectral properties of the light beam 816 may be adjusted in other ways. For example, the spectral properties, such as the spectral bandwidth and center wavelength, of the light beam 816 may be adjusted by controlling a pressure and/or gas concentration of the gaseous gain medium of the chamber 815. For implementations in which the light-generation module 810 is an excimer source, the spectral properties (for example, the spectral bandwidth or the center wavelength) of the light beam 816 may be adjusted by controlling the pressure and/or concentration of, for example, fluorine, chlorine, argon, krypton, xenon, and/or helium in the chamber 815.

The pressure and/or concentration of the gaseous gain medium 819 is controllable with a gas supply system 890. The gas supply system 890 is fluidly coupled to an interior of the discharge chamber 815 via a fluid conduit 889. The fluid conduit 889 is any conduit that is capable of transporting a gas or other fluid with no or minimal loss of the fluid. For example, the fluid conduit 889 may be a pipe that is made of or coated with a material that does not react with the fluid or fluids transported in the fluid conduit 889. The gas supply system 890 includes a chamber 891 that contains and/or is configured to receive a supply of the gas or gasses used in the gain medium 819. The gas supply system 890 also includes devices (such as pumps, valves, and/or fluid switches) that enable the gas supply system 890 to remove gas from or inject gas into the discharge chamber 815. The gas supply system 890 is coupled to the control system 805.

The optical oscillator 812 also includes a spectral analysis apparatus 898. The spectral analysis apparatus 898 is a measurement system that may be used to measure or monitor the wavelength of the light beam 816. In the example shown in FIG. 8A, the spectral analysis apparatus 898 receives light from the output coupler 896.

The light-generation module 810 may include other components and systems. For example, the light-generation module 810 may include a beam preparation system 899. The beam preparation system 899 may include a pulse stretcher that stretches each pulse that interacts with the pulse stretcher in time. The beam preparation system also may include other components that are able to act upon light such as, for example, reflective and/or refractive optical elements (such as, for example, lenses and mirrors), and/or filters. In the example shown, the beam preparation system 899 is positioned in the path of the exposure beam 816. However, the beam preparation system 899 may be placed at other locations within the system 800.

The system 800 also includes the scanner apparatus 880. The scanner apparatus 880 exposes the wafer 882 with a shaped exposure beam 816A. The shaped exposure beam 816A is formed by passing the exposure beam 816 through a projection optical system 881. The scanner apparatus 880 may be a liquid immersion system or a dry system. The scanner apparatus 880 includes a projection optical system 881 through which the exposure beam 816 passes prior to reaching the wafer 882, and a sensor system or metrology system 870. The wafer 882 is held or received on a wafer holder 883. The scanner apparatus 880 also may include, for example, temperature control devices (such as air conditioning devices and/or heating devices), and/or power supplies for the various electrical components.

The metrology system 870 includes a sensor 871. The sensor 871 may be configured to measure a property of the shaped exposure beam 816A such as, for example, bandwidth, energy, pulse duration, and/or wavelength. The sensor 871 may be, for example, a camera or other device that is able to capture an image of the shaped exposure beam 816A at the wafer 882, or an energy detector that is able to capture data that describes the amount of optical energy at the wafer 882 in the x-y plane.

Referring also to FIG. 8B, the projection optical system 881 includes a slit 884, a mask 885, and a projection objective, which includes a lens system 886. The lens system 886 includes one or more optical elements. The exposure beam 816 enters the scanner apparatus 880 and impinges on the slit 884, and at least some of the output light beam 816 passes through the slit 884 to form the shaped exposure beam 816A. In the example of FIGS. 8A and 8B, the slit 884 is rectangular and shapes the exposure beam 816 into an elongated rectangular shaped light beam, which is the shaped exposure beam 816A. The mask 885 includes a pattern that determines which portions of the shaped light beam are transmitted by the mask 885 and which are blocked by the mask 885. Microelectronic features are formed on the wafer 882 by exposing a layer of radiation-sensitive photoresist material on the wafer 882 with the exposure beam 816A. The design of the pattern on the mask is determined by the specific microelectronic circuit features that are desired.

The configuration shown in FIG. 8A is an example of a configuration for a DUV system. Other implementations are possible. For example, the light-generation module 810 may include N instances of the optical oscillator 812, where N is an integer number greater than one. In these implementations, each optical oscillator 812 is configured to emit a respective light beam toward a beam combiner, which forms the exposure beam 816.

FIG. 9 shows another example configuration of a DUV system. FIG. 9 is a block diagram of a photolithography system 900 that includes a light-generation module 910 that produces a pulsed light beam 916, which is provided to the scanner apparatus 880. The control system 805 is coupled to various components of the light-generation module 910 and the scanner apparatus 880 to control various operations of the system 900. The light-generation module 910 is used with the switching network 450.

The light-generation module 910 is a two-stage laser system that includes a master oscillator (MO) 912_1 that provides the seed light beam 918 to a power amplifier (PA) 912_2. The PA 912_2 receives the seed light beam 918 from the MO 912_1 and amplifies the seed light beam 918 to generate the light beam 916 for use in the scanner apparatus 880. For example, in some implementations, the MO 912_1 may emit a pulsed seed light beam, with seed pulse energies of approximately 1 milliJoule (mJ) per pulse, and these seed pulses may be amplified by the PA 912_2 to about 6 to 15 mJ, but other energies may be used in other examples.

The MO 912_1 includes a discharge chamber 915_1 having two elongated electrodes 913a_1 and 913b_1, a gain medium 919_1 (shown with light dotted shading in FIG. 9) that is a gas mixture, and a fan (not shown) for circulating the gas mixture between the electrodes 913a_1, 913b_1. A resonator is formed between a line narrowing module 995 on one side of the discharge chamber 915_1 and an output coupler 996 on a second side of the discharge chamber 915_1.

The discharge chamber 915_1 includes a first chamber window 963_1 and a second chamber window 964_1. The first and second chamber windows 963_1 and 964_1 are on opposite sides of the discharge chamber 915_1. The first and second chamber windows 963_1 and 964_1 transmit light in the DUV range and allow DUV light to enter and exit the discharge chamber 915_1.

The line narrowing module 995 may include a diffractive optic such as a grating that finely tunes the spectral output of the discharge chamber 915_1. The light-generation module 910 also includes a line center analysis module 968 that receives an output light beam from the output coupler 996 and a beam coupling optical system 969. The line center analysis module 968 is a measurement system that may be used to measure or monitor the wavelength of the seed light beam 918. The line center analysis module 968 may be placed at other locations in the light-generation module 910, or it may be placed at the output of the light-generation module 910.

The gas mixture that is the gain medium 9191 may be any gas suitable for producing a light beam at the wavelength and bandwidth required for the application. For an excimer source, the gas mixture may contain a noble gas (rare gas) such as, for example, argon or krypton, a halogen, such as, for example, fluorine or chlorine and traces of xenon apart from a buffer gas, such as helium. Specific examples of the gas mixture include argon fluoride (ArF), which emits light at a wavelength of about 193 nm, krypton fluoride (KrF), which emits light at a wavelength of about 248 nm, or xenon chloride (XeCl), which emits light at a wavelength of about 351 nm. Thus, the light beams 916 and 918 include wavelengths in the DUV range in this implementation. The excimer gain medium (the gas mixture) is pumped with short (for example, nanosecond) current pulses in a high-voltage electric discharge by application of a voltage to the elongated electrodes 913a 1, 913b_1.

The PA 912_2 includes a beam coupling optical system 969 that receives the seed light beam 918 from the MO 912_1 and directs the seed light beam 918 through a discharge chamber 9152, and to a beam turning optical element 992, which modifies or changes the direction of the seed light beam 918 so that it is sent back into the discharge chamber 915_2. The beam turning optical element 992 and the beam coupling optical system 969 form a circulating and closed loop optical path in which the input into a ring amplifier intersects the output of the ring amplifier at the beam coupling optical system 969.

The discharge chamber 915_2 includes a pair of elongated electrodes 913a2, 913b_2, a gain medium 919_2 (shown with light dotted shading in FIG. 9), and a fan (not shown) for circulating the gain medium 919_2 between the electrodes 913a2, 913b_2. The gas mixture that forms the gain medium 919_2 may be the same as the gas mixture that forms gain medium 919_1.

The discharge chamber 915_2 includes a first chamber window 963_2 and a second chamber window 964_2. The first and second chamber windows 963_2 and 964_2 are on opposite sides of the discharge chamber 915_2. The first and second chamber windows 963_2 and 964_2 transmit light in the DUV range and allow DUV light to enter and exit the discharge chamber 915_2.

When the gain medium 919_1 or 919_2 is pumped by creating a potential difference between the electrodes 913a 1, 913b_1 or 913a_2, 913b_2, respectively, the gain medium 919_1 and/or 919_2 emits light. The repetition rate of the pulses may range between about 500 and 6,000 Hz for various applications. In some implementations, the repetition rate may be greater than 6,000 Hz, and may be, for example, 12,000 Hz or greater, but other repetition rates may be used in other implementations.

The potential difference between the electrodes 913a_1 and 913b_1 is created using the commutator 471_1 and compression head 472_1 discussed with respect to FIG. 4. The potential difference between the electrodes 913a_2 and 913b_2 is created using the commutator 471_2 and the compression head 472_2 discussed with respect to FIG. 4.

The output light beam 916 may be directed through a beam preparation system 999 prior to reaching the scanner apparatus 880. The beam preparation system 999 may include a bandwidth analysis module that measures various parameters (such as the bandwidth or the wavelength) of the beam 916. The beam preparation system 999 also may include a pulse stretcher that stretches each pulse of the output light beam 916 in time. The beam preparation system 999 also may include other components that are able to act upon the beam 916 such as, for example, reflective and/or refractive optical elements (such as, for example, lenses and mirrors), filters, and optical apertures (including automated shutters).

The DUV light-generation module 910 also includes the gas management system 990, which is in fluid communication with an interior 978 of the DUV light-generation module 910.

The embodiments can be further described using the following clauses:
1. A system comprising:
a first optical subsystem configured to produce a pulsed seed light beam, the first optical subsystem comprising:
a first chamber configured to hold a first gaseous gain medium; and
a first excitation mechanism in the first chamber;
a second optical subsystem configured to produce a pulsed output light beam based on the pulsed seed light beam, the second optical subsystem comprising:
a second chamber configured to hold a second gaseous gain medium; and
a second excitation mechanism in the second chamber;
a first magnetic switching network configured to activate the first excitation mechanism, wherein activating the first excitation mechanism causes the first optical subsystem to produce a pulse of the pulsed seed light beam, and the first magnetic switching network comprises:
a first initial energy storage node,
a first additional energy storage node,
a first magnetic switch electrically connected to the first additional energy storage node, and
a first inductor between the first initial energy storage node and the first additional energy storage node, and wherein the first initial energy storage node is configured to receive electrical current from an electrical charger;
a second magnetic switching network configured to activate the second excitation mechanism, wherein activating the second excitation mechanism causes the second optical subsystem to produce a pulse of the pulsed output light beam, and the second magnetic switching network comprises:
a second initial energy storage node,
a second additional energy storage node,
a second magnetic switch electrically connected to the second additional energy storage node, and
a second inductor between the second initial energy storage node and the second additional energy storage node, and wherein the second initial energy storage node is configured to receive electrical current from the electrical charger; and
an electronic network electrically connected to the first additional energy storage node and the second additional energy storage node, wherein the electronic network is configured to control a voltage difference between the first additional energy storage node and the second additional energy storage node.
2. The system of clause 1, wherein the electronic network is configured to control the voltage difference between the first additional energy storage node and the second additional energy storage node by reducing the voltage difference.
3. The system of clause 2, wherein the electronic network is configured to control the voltage difference between the first additional energy storage node and the second additional energy storage node by eliminating the voltage difference.
4. The system of clause 3, wherein eliminating the voltage difference comprises causing the first additional energy storage node and the second additional energy storage node to be at the same voltage.
5. The system of clause 1, wherein the first additional energy storage node comprises a first energy storage device, and the second additional energy storage node comprises a second energy storage device.
6. The system of clause 5, wherein the electronic network is configured to control the voltage difference between the first additional energy storage node and the second additional energy storage node only when the electronic network is in an active state, and the electronic network is in the active state when the first energy storage device and the second energy storage device are accumulating electrical charge.
7. The system of clause 5, wherein the electronic network is configured to control the voltage difference between the first additional energy storage node and the second additional energy storage node only when the electronic network is in an active state, the electronic network is in the active state at a first time, and the electronic network transitions out of the active state a pre-defined amount of time after the first time.
8. The system of clause 1, wherein the electronic network is configured to control the voltage difference between the first additional energy storage node and the second additional energy storage node only when in an active state,
the electronic network is in the active state after the first magnetic switching network activates the first excitation mechanism and the second magnetic switching network activates the second excitation mechanism, and
the electronic network transitions out of the active state prior to a subsequent activation of the first excitation mechanism and prior to a subsequent activation of the second excitation mechanism.
9. The system of clause 1, wherein the electronic network is configured to control the voltage difference between the first additional energy storage node and the second additional energy storage node only when in an active state, and
the electronic network is configured to be in the active state after each activation of the first and second excitation mechanisms and to transition out of the active state before the next activation of the first excitation mechanism and the second excitation mechanism.
10. The system of clause 1, wherein each of the first additional energy storage node and the second additional energy storage node comprises at least one capacitor.
11. The system of clause 1, wherein the first additional energy storage node is one of a plurality of additional storage nodes in the first magnetic switching network, and the second additional energy storage node is one of a plurality of additional storage nodes in the second magnetic switching network, and the system further comprises a second electronic network electrically connected to one of the additional storage nodes in the first magnetic switching network other than the first additional energy storage node and to one of the additional storage nodes in the second magnetic switching network other than the second additional energy storage node.
12. The system of clause 11, wherein at least one of the plurality of additional storage nodes in the first magnetic switching network is a primary side of a transformer, and at least one of the plurality of additional storage nodes in the second magnetic switching network is a primary side of a transformer.
13. The system of clause 1, wherein the electronic network comprises at least two transistors.
14. The system of clause 1, wherein the electronic network comprises a plurality of controllable switches, and each controllable switch is in parallel with a resistive network.
15. The system of clause 14, further comprising a ground path network between the electronic network and ground.
16. The system of clause 15, wherein the ground path network comprises a transistor and a resistor.
17. The system of clause 1, wherein the electronic network comprises:
a first electronic network electrically connected between the first additional energy storage node and ground; and
a second electronic network electrically connected between the second additional energy storage node and ground.
18. The system of clause 17, wherein each of the first electronic network and the second electronic network comprises a voltage-controlled switch in series with a resistive element.
19. The system of clause 1, wherein the first initial energy storage node and the second initial energy storage node being configured to receive electrical current from the electrical charger comprises the first initial energy storage node and the second initial energy storage node being configured to receive electrical current from a resonant charger.
20. The system of clause 1, further comprising a second electronic network, wherein the second electronic network is electrically connected to an anode of a diode that is electrically connected to the first initial energy storage node and to an anode of a diode that is electrically connected to the second initial energy storage node.
21. The system of clause 1, further comprising a second electronic network, wherein the second electronic network is electrically connected to a cathode of a diode that is electrically connected to the first initial energy storage node and to a cathode of a diode that is electrically connected to the second initial energy storage node.
22. The system of clause 1, wherein the first magnetic switching network further comprises a first switch configured to control an electrical connection between the first initial energy storage node and the first additional energy storage node, and the second magnetic switching network further comprises a second switch configured to control an electrical connection between the second initial energy storage node and the second additional energy storage node.
23. The system of clause 1, wherein the first magnetic switch comprises a first saturable reactor, and the second magnetic switch comprises a second saturable reactor.
24. An apparatus comprising:
a magnetic switching network configured to activate an excitation mechanism in a discharge chamber, wherein the magnetic switching network comprises:
an initial energy storage node configured to receive electrical current from an electrical charger; an additional energy storage node; and at least one electrical element between the initial energy storage node and the additional energy storage node; and
an electronic network electrically connected to the additional energy storage node, the electronic network configured to control a voltage at the additional energy storage node.
25. The apparatus of clause 24, wherein the electronic network comprises at least one controllable switch, and the controllable switch comprises a first state in which current does not flow in the controllable switch and a second state in which current flows in the controllable switch.
26. The apparatus of clause 25, wherein the controllable switch is controlled to be in the first state when an energy storage device electrically connected to the additional energy storage node is receiving electrical charge.
27. The apparatus of clause 26, wherein the controllable switch is controlled to be in the second state when the energy storage device is discharging electrical charge.
28. The apparatus of clause 25, wherein the controllable switch is controlled to be in the first state after an energy storage device electrically connected to the additional energy storage node has received a threshold amount of electrical charge.
29. The apparatus of clause 25, wherein the controllable switch is controlled to be in the first state after the magnetic switching network activates the excitation mechanism a first time, and the controllable switch is controlled to be in the second state before the magnetic switching network activates the excitation mechanism a second time.
30. The apparatus of clause 29, wherein the first time and the second time are consecutive activations of the excitation mechanism.
31. The apparatus of clause 25, wherein, between any two consecutive activations of the excitation mechanism, the controllable switch is controlled to be in the first state and is then controlled to transition from the first state to the second state.
32. A control system comprising:
a control interface configured to trigger an electronic network, the electronic network electrically connected to a first energy storage node in a first magnetic switching network and to a second energy storage node in a second magnetic switching network, wherein each of the first magnetic switching network and the second magnetic switching network further comprise an initial energy storage node that receives electrical charge from a resonant charger; and
a switch control configured to command the control interface to:
provide a trigger to the electronic network to thereby cause the electronic network to electrically connect the first energy storage node to the second energy storage node and to reduce a voltage difference between the first energy storage node and the second energy storage node.

These and other implementations are within the scope of the claims.

1. A system comprising:
a first optical subsystem configured to produce a pulsed seed light beam, the first optical subsystem comprising:
a first chamber configured to hold a first gaseous gain medium; and
a first excitation mechanism in the first chamber;
a second optical subsystem configured to produce a pulsed output light beam based on the pulsed seed light beam, the second optical subsystem comprising:
a second chamber configured to hold a second gaseous gain medium; and
a second excitation mechanism in the second chamber;
a first magnetic switching network configured to activate the first excitation mechanism, wherein activating the first excitation mechanism causes the first optical subsystem to produce a pulse of the pulsed seed light beam, and the first magnetic switching network comprises:
a first initial energy storage node,
a first additional energy storage node,
a first magnetic switch electrically connected to the first additional energy storage node, and
a first inductor between the first initial energy storage node and the first additional energy storage node, and wherein the first initial energy storage node is configured to receive electrical current from an electrical charger;
a second magnetic switching network configured to activate the second excitation mechanism, wherein activating the second excitation mechanism causes the second optical subsystem to produce a pulse of the pulsed output light beam, and the second magnetic switching network comprises:
a second initial energy storage node,
a second additional energy storage node,
a second magnetic switch electrically connected to the second additional energy storage node, and
a second inductor between the second initial energy storage node and the second additional energy storage node, and wherein the second initial energy storage node is configured to receive electrical current from the electrical charger; and
an electronic network electrically connected to the first additional energy storage node and the second additional energy storage node, wherein the electronic network is configured to control a voltage difference between the first additional energy storage node and the second additional energy storage node.

2. The system of claim 1, wherein the electronic network is configured to control the voltage difference between the first additional energy storage node and the second additional energy storage node by reducing or eliminating the voltage difference.

3.-5. (canceled)

6. The system of claim 1, wherein the first additional energy storage node comprises a first energy storage device, and the second additional energy storage node comprises a second energy storage device and the electronic network is configured to control the voltage difference between the first additional energy storage node and the second additional energy storage node only when the electronic network is in an active state, and the electronic network is in the active state when the first energy storage device and the second energy storage device are accumulating electrical charge.

7. (canceled)

8. (canceled)

9. The system of claim 1, wherein the electronic network is configured to control the voltage difference between the first additional energy storage node and the second additional energy storage node only when in an active state, and
the electronic network is configured to be in the active state after each activation of the first and second excitation mechanisms and to transition out of the active state before the next activation of the first excitation mechanism and the second excitation mechanism.

10. (canceled)

11. The system of claim 1, wherein the first additional energy storage node is one of a plurality of additional storage nodes in the first magnetic switching network, and the second additional energy storage node is one of a plurality of additional storage nodes in the second magnetic switching network, and the system further comprises a second electronic network electrically connected to one of the additional storage nodes in the first magnetic switching network other than the first additional energy storage node and to one of the additional storage nodes in the second magnetic switching network other than the second additional energy storage node.

12. The system of claim 11, wherein at least one of the plurality of additional storage nodes in the first magnetic switching network is a primary side of a first transformer, and at least one of the plurality of additional storage nodes in the second magnetic switching network is a primary side of a second transformer.

13. (canceled)

14. The system of claim 1, wherein the electronic network comprises a plurality of controllable switches, and each controllable switch is in parallel with a resistive network.

15. The system of claim 14, further comprising a ground path network between the electronic network and ground, wherein the ground path network comprises a transistor and a resistor.

16. (canceled)

17. The system of claim 1, wherein the electronic network comprises:
a first electronic network electrically connected between the first additional energy storage node and ground; and
a second electronic network electrically connected between the second additional energy storage node and ground.

18. The system of claim 17, wherein each of the first electronic network and the second electronic network comprises a voltage-controlled switch in series with a resistive element.

19. The system of claim 1, wherein the first initial energy storage node and the second initial energy storage node being configured to receive electrical current from the electrical charger comprises the first initial energy storage node and the second initial energy storage node being configured to receive electrical current from a resonant charger.

20. The system of claim 1, further comprising a second electronic network, wherein the second electronic network is electrically connected to an anode of a diode that is electrically connected to the first initial energy storage node and to an anode of a diode that is electrically connected to the second initial energy storage node.

21. (canceled)

22. The system of claim 1, wherein the first magnetic switching network further comprises a first switch configured to control an electrical connection between the first initial energy storage node and the first additional energy storage node, and the second magnetic switching network further comprises a second switch configured to control an electrical connection between the second initial energy storage node and the second additional energy storage node.

23. The system of claim 1, wherein the first magnetic switch comprises a first saturable reactor, and the second magnetic switch comprises a second saturable reactor.

24. An apparatus comprising:
a magnetic switching network configured to activate an excitation mechanism in a discharge chamber, wherein the magnetic switching network comprises:
an initial energy storage node configured to receive electrical current from an electrical charger;
an additional energy storage node; and at least one electrical element between the initial energy storage node and the additional energy storage node; and
an electronic network electrically connected to the additional energy storage node, the electronic network configured to control a voltage at the additional energy storage node.

25. The apparatus of claim 24, wherein the electronic network comprises at least one controllable switch, and the controllable switch comprises a first state in which current does not flow in the controllable switch and a second state in which current flows in the controllable switch.

26. The apparatus of claim 25, wherein the controllable switch is controlled to be in the first state when an energy storage device electrically connected to the additional energy storage node is receiving electrical charge and the controllable switch is controlled to be in the second state when the energy storage device is discharging electrical charge.

27. (canceled)

28. The apparatus of claim 25, wherein the controllable switch is controlled to be in the first state after an energy storage device electrically connected to the additional energy storage node has received a threshold amount of electrical charge.

29. The apparatus of claim 25, wherein the controllable switch is controlled to be in the first state after the magnetic switching network activates the excitation mechanism a first time, and the controllable switch is controlled to be in the second state before the magnetic switching network activates the excitation mechanism a second time.

30. (canceled)

31. The apparatus of claim 25, wherein, between any two consecutive activations of the excitation mechanism, the controllable switch is controlled to be in the first state and is then controlled to transition from the first state to the second state.

32. A control system comprising:
a control interface configured to trigger an electronic network, the electronic network electrically connected to a first energy storage node in a first magnetic switching network and to a second energy storage node in a second magnetic switching network, wherein each of the first magnetic switching network and the second magnetic switching network further comprise an initial energy storage node that receives electrical charge from a resonant charger; and
a switch control configured to command the control interface to:
provide a trigger to the electronic network to thereby cause the electronic network to electrically connect the first energy storage node to the second energy storage node and to reduce a voltage difference between the first energy storage node and the second energy storage node.
